(19) United States
(12) Patent Application Publication
(10) Pub. No.: US 2012/0260138 A1
(43) Pub. Date: Oct. 11, 2012

(54) ERROR LOGGING IN A STORAGE DEVICE

(76) Inventors: Robert L. Downing, III, Spring, TX (US); Walter W. Bellamy, Spring, TX (US); Terry W. Denney, Houston, TX (US)

(21) Appl. No.: 13/080,041

(22) Filed: Apr. 5, 2011

(51) Int. Cl. G11C 29/04; G06F 11/22

(52) U.S. Cl. 714/723; 714/E11.145

(57) ABSTRACT

The present disclosure provides a method for operating a storage drive. The method includes receiving a storage command from an initiator and generating an error in response to the storage command. The method also includes adding a check condition data parameter to a check condition log stored to a storage media of the storage drive. The check condition data parameter comprises a physical memory address corresponding to a physical location of a storage element corresponding to the error.

### BACKGROUND

Storage devices such as hard disk drives and solid state drives are widely used in a variety of computing systems. During operation, such storage devices will generally experience some number of errors, which may be due to defective storage elements, among other causes. Some types of errors may be reported to the host and may also be handled internally by the drive itself, such as by relocating data from defective storage elements to new storage elements. In some cases, errors may be stored to an error log. Analysis of the error log may enable a user or technician to diagnose problems that may exist in the drive. Often such error logs are limited in terms of the amount of errors recorded and the type of information recorded for each error.

### BRIEF DESCRIPTION OF THE DRAWINGS

Certain embodiments are described in the following detailed description and in reference to the drawings, in which:

FIG. 1 is a block diagram of a computer system with storage drives configured to generate a check condition log page, in accordance with an embodiment;

FIG. 2 is a block diagram of a data storage drive configured to generate a check condition log page, in accordance with an embodiment;

FIG. 3 is a block diagram of an example of a check condition log status parameter, in accordance with an embodiment;

FIG. 4 is a block diagram of an example of a check condition log data parameter, in accordance with an embodiment;

FIG. 5 is a process flow diagram of a method of operating a storage drive, in accordance with an embodiment; and

FIG. 6 is a block diagram showing a non-transitory, computer-readable medium that stores code for operating a drive controller, in accordance with an embodiment.

### DETAILED DESCRIPTION

Exemplary embodiments relate to systems and methods for generating a check condition log page. Various embodiments described herein provide a storage drive configured to store a check condition log page to the main storage media of the drive. As used herein, a “check condition” error is an error that is reported by a Small Computer System Interface (SCSI) device to the host, also known as the “initiator,” in response to a command from the host. The check condition log page can include a variety of information related to each check condition error reported to the host, and this information may be gathered at the time that the error occurs.

Hard disk drives will often reallocate recoverable media errors by moving the related logical block address (LBA) to a different physical memory address. Solid state drives regularly relocate logical block addresses to different physical memory addresses, for example, as part of a wear-leveling routine. Thus, merely knowing the logical block address corresponding to an error does not always reveal the physical memory address corresponding to the error, because the logical block address may have been remapped to a new physical location. In an embodiment, the check condition log page includes the physical memory address of the storage element corresponding to the reported error.

The check condition log page described herein can have a number of beneficial uses. For example, a drive manufacturer or computer system manufacturer may perform various tests on a drive, including a stress test of the drive's firmware. Such a stress test will generally return a large number of errors, many of which may be media related errors. Upon detection of an error during such a test, the check condition log page can be accessed to find the last error with matching initiator address, command descriptor block (CDB), and sense data, retrieve the physical memory address for that error, and check that physical memory address against the list of known bad media locations. The list of known bad media locations may be obtained using an SCSI Read Defect Data command, which can be used to retrieve a defect list in the form of physical addresses. Errors that occur on known defective media locations can be forgiven, which saves time and effort that would otherwise be spent investigating each error. Furthermore, the check condition log page can be a valuable tool for analyzing drive errors that occur during normal use. For example, the check condition log page on a drive returned by a customer or in use at a customer site can be used to provide a list of a large number of recent errors. Since the physical memory address corresponding to each error is stored to the check condition log page, the media location of each error can be determined even if the logical block address corresponding to the error has been relocated by the drive. Therefore, the check condition log page may provide better insight into the field behavior of the drive.

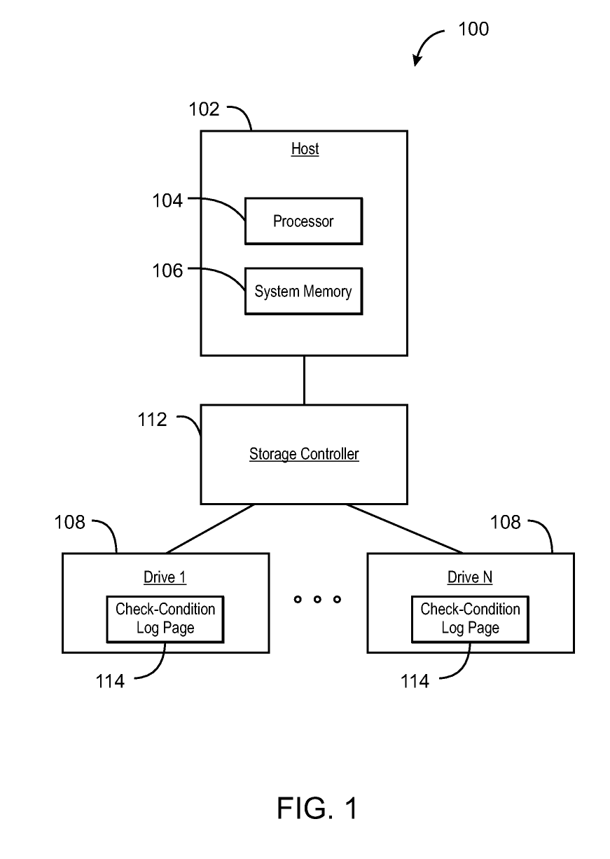

FIG. 1 is a block diagram of a computer system with storage drives configured to generate a check condition log page, in accordance with an embodiment. The computer system is generally referred to by the reference number 100. The computer system 100 may include hardware elements including circuitry, software elements including computer code stored on a machine-readable medium or a combination of both hardware and software elements. Additionally, the functional blocks shown in FIG. 1 are but one example of functional blocks that may be implemented in an exemplary embodiment of the present invention. Those of ordinary skill in the art would readily be able to define specific functional blocks based on design considerations for a particular computer system.

The computer system 100 may include a computing device referred to as host 102, which may be a general purpose computer such as a desktop or a server, for example. The host 102 includes a processor 104 coupled to a system memory 106. The processor 104, which may be a central processing unit (CPU), is adapted to control the overall operation of the host 102 and may be coupled to the system memory 106 through a memory controller. The system memory 106 may include a volatile memory region such as RAM used by the processor 104 to execute the various software programs running on the processor 104, such as an operating system, applications, device drivers, and the like. The host 102 may also include user interface devices, such as a monitor and a keyboard to provide user control of the host 102.

As shown in FIG. 1, the computer system 100 may include one or more storage drives 108 operatively coupled to the host 102 through a storage controller 112, such as an array controller, SCSI controller, and the like. The storage drives 108 can include any electronic storage device used for non-volatile storage of data, including hard disk drives (HDDs) and solid state drives (SSDs), among others. In an embodiment, the storage drives 108 may be Small Computer System Interface (SCSI) devices.

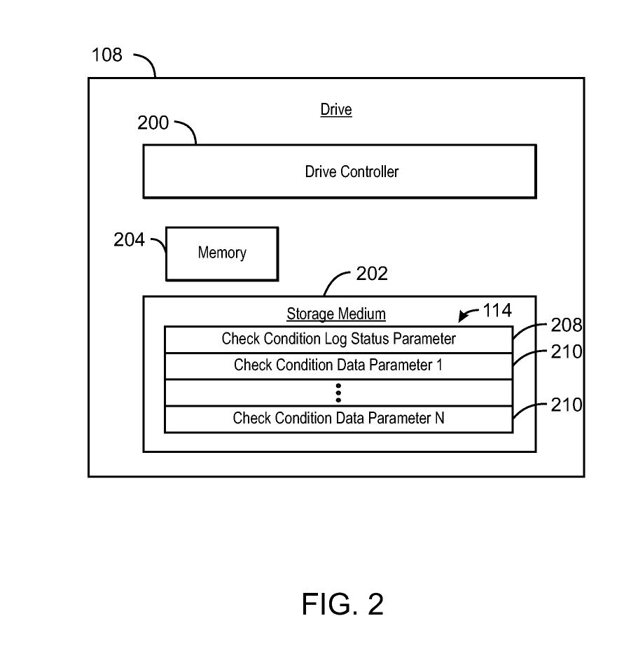

As shown in FIG. 1, the drives 108 may include a check condition log page 114. The check condition log page 114 is used to store check condition errors that have been reported to the storage controller 112 in response to a storage command from the storage controller 112. To retrieve the data stored to the check condition log page 114, the storage controller 112 or an application running on the host 102 may send a Log Sense command to the storage drive 108. The Log Sense command identifies the check condition log page 114 and specifies a data transfer length and a parameter pointer. The parameter pointer specifies an offset into the check condition log page, and the data transfer length specifies how much data to return. In response to the Log Sense command, a drive may send the contents of the check condition log page 114 to the storage controller 112 or an application running on host 102, where the log data may be viewed by a user or analyzed by software running on the host. The contents of the check condition log page 114 are described further below in reference to FIGS. 2-4.

FIG. 2 is a block diagram of a data storage drive configured to generate a check condition log page, in accordance with an embodiment. As described above, the drive 108 may be any suitable type of non-volatile storage device, including a hard disk drive and a solid state drive, among others. The drive 108 may include a drive controller 200 configured to control various operations of the drive 108. The drive controller 200 processes commands received from an initiator, which may be the storage controller 112 or the host 102. Commands received from the initiator may include storage read commands, storage write commands, and Log Sense commands, among others. The drive 108 may also include a storage medium 202, which includes a non-volatile memory used for long-term storage of data received from the host 102. As used herein, the term “storage medium” refers to the main storage medium of the drive 108 as opposed to other memory devices such as read-only memory (ROM), caches, data buffers, and the like. The storage medium 202 may include one or more magnetic disks or solid state memory such as NAND-based flash memory. The drive controller 200 may map the physical locations of the storage medium into logical block addresses. Storage operations received from the host 102 or the storage controller 112 may reference these logical block addresses. To process the storage operations received from the host 102 or storage controller 112, the drive controller 200 translates the logical block addresses into actual physical memory address that references a specific physical memory location of the storage medium. In embodiments, the drive controller 200 may remap the logical block addresses to different physical memory addresses. For example, in a hard disk drive, logical block addresses may be remapped in response to read or write errors that indicate a defective sector. In a solid state drive, logical block addresses may be remapped on a periodic basis as part of a wear-leveling routine, for example. Such remapping will generally occur in a manner that is transparent to the host 102 and the storage controller 112.

The drive 108 may also include a non-transitory, computer-readable memory such as memory 204 for storing code such as device firmware. The memory 204 may include any type of volatile or non-volatile memory such as NAND flash memory, among others. The drive controller 200 may retrieve and execute instructions stored in the memory 204 to process various operations of the drive 108, including operations in accordance with an embodiment describe herein, such as generating the check condition log page 114. The drive 108 may also include volatile memory such as a cache used to store frequently accessed data or to buffer data being sent to or retrieved from the storage medium 202.

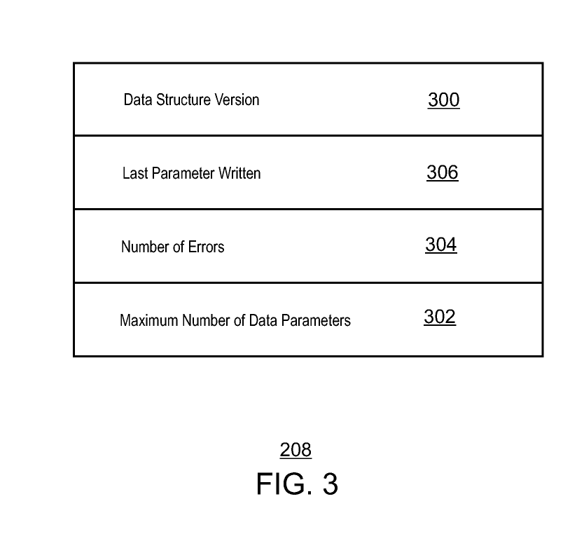

The check condition log page 114 may be stored to the storage medium 202 and may include a check condition log status parameter 208 and one or more check condition data parameters 210. The check condition log status parameter 208 provides higher-level status information about the state of the check condition log page 114, including information about the subsequent check condition data parameters 210. For example, the check condition log status parameter 208 includes information such as the number of recorded check condition data parameters, the maximum number of recordable check condition data parameters, and the like. An example of a check condition log status parameter 208 is described below in reference to FIG. 3.

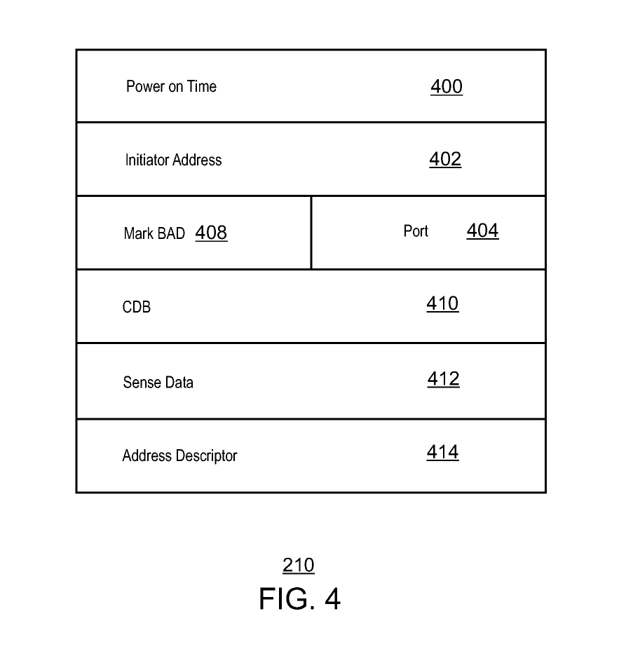

Each check condition data parameter 210 includes data relating to specific errors or conditions encountered by the drive 108. In an embodiment, each check condition data parameter 210 contains data relating to check condition errors reported to the host 102 or storage controller 112. For example, a check condition error may be caused by various conditions which prevent the drive 108 from executing an operation requested by the host 102 or storage controller 112, such as a defective media element, among others. A check condition error may also be a notification that the command succeeded, but the drive has detected some unrelated problem. For example, the drive may have detected a temperature excursion or early signs of an impending problem. In an embodiment, only check condition errors are stored to the check condition log page. For example, other error conditions such as BUSY status, RESERVATION CONFLICT status, or internal errors that are not reported to the host 102 may not be stored to the check condition log page 114. The check condition log page 114 may include any suitable number of check condition data parameters 210, for example, 1000 to 65,535 or more. An example of a check condition data parameter 210 is described below in reference to FIG. 4.

Each time that a check condition occurs, the drive controller 200 reports the check condition to the host 102 and gathers the data to be stored to the check condition log page 114, including the physical memory address corresponding to the check condition. The drive controller 200 may then generate a new check condition data parameter 210 and populate the check condition data parameter 210 with the gathered data. In an embodiment, the check condition data parameter 210 may be written to the check condition log page 114 upon the occurrence of the check condition error. In an embodiment, the data corresponding to the check condition error may first be stored to a temporary storage location, such as the memory 204. The check condition log page 114 may be periodically updated based on the check condition data stored to the memory 204. For example, the check condition data may be transferred from the cache to the check condition log page 114 after a specified time interval, for example, one minute, ten minutes, thirty minutes, one hour, twelve hours, or more. The check condition data may be gathered at or near the time that the error occurs and before any potential remapping of the logical block addresses corresponding to the error can take place.

FIG. 3 is a block diagram of an example of a check condition log status parameter, in accordance with an embodiment. As noted above, the check condition log status parameter 208 provides higher-level status information about the state of the check condition log page 114. The check condition log status parameter may be updated by the drive controller 200 each time a new check condition data parameter 210 is added to the check condition log page 114.

As shown in FIG. 3, the check condition log status parameter 208 may include a variety of values, including a data structure version 300, a maximum number of data parameters 302, number of errors 304, and last parameter written 306, among others. The data structure version 300 indicates the version of the check condition log page 114 and may be used to determine the format of the check condition log page 114, which may be different for different drives 108 due, for example, to different firmware versions. The maximum number of data parameters 302 is a fixed value that indicates the maximum number of check condition data parameters 210 that can be stored to the check condition log page 114. The number of errors 304 is a value that indicates the total number of check condition errors that have been stored to the check condition log page 114. The number of errors 304 may be incremented by one each time a new check condition data parameter 210 is stored to the check condition log page 114. As described further below, the number of errors 304 may be a value greater than the value indicated by the maximum number of data parameters 302. The last parameter written 306 is a value that indicates which check condition data parameter 210 was the last to be stored to the check condition log page 114.

In an embodiment, if the number of check condition errors encountered reaches the maximum number of check condition data parameters 210, or a multiple thereof, future check condition data parameters 210 may be wrapped around to the beginning of the check condition log page 114 such that the oldest check condition data parameter 210 is overwritten with the new check condition data. For example, if a check condition error is encountered after the check condition log page 114 is full (number of errors 304 equals maximum number of data parameters 302), the drive controller 200 may overwrite the first check condition data parameter 210 with a new check condition data parameter 210 corresponding to the most recent check condition error. In this example, last parameter written 306 will equal one and number of errors 304 will equal maximum number of data parameters 302 plus one. The next check condition data parameter 210 would be stored to position two, again overwriting the oldest check condition data parameter 210, and so on. In this way, the check condition log page 114 may store the most recent check condition errors, and number of errors 304 will provide an indication of how many check condition errors actually occurred, including those that may have been overwritten. The check condition data parameters 210 may be wrapped any number of times.

FIG. 4 is a block diagram of an example of a check condition data parameter, in accordance with an embodiment. As shown in FIG. 4, the check condition data parameter 210 may include a power on seconds value 400, initiator address 402, port value 404, mark bad 408, CDB (Command Descriptor Block) value 410, sense data 412, and an address descriptor 414.

The power on time value 400 may be used as a time stamp to indicate a time that the corresponding error occurred. The power on time value 400 may indicate the number of seconds that drive 108 has been powered on at the time of the error. The initiator address 402 is the address of the initiator that sent the command associated with the check condition error and may be a serial attached small computer systems interface (SAS) address, for example. The port value 404 is a value that indicates the port that returned the error.

The mark bad value 408 may be a bit that is set if the media error is returned due to the logical block address being marked “bad” due to a previous media error at a different physical location. For example, a solid state drive may return an unrecoverable read error at LBA (logical block address) x due to a NAND media error at physical location y, in which case the MARK BAD bit for this error may be 0. The solid state drive may later move that LBA x to a new physical location z, due to garbage collection, or other LBAs in the page being written, or some other reason. The solid state drive will generally return an unrecoverable read error for any reads to LBA x until LBA x has been re-written. Any subsequent unrecoverable read errors for LBA x, before LBA x has been re-written with user data, may have the MARK BAD bit set to 1.

The CDB value 410 includes the command descriptor block (CDB) associated with the error. The CDB is used to communicate storage commands to SCSI devices, and may include a one byte operation code followed by some command-specific parameters. Each CDB can be a total of 6, 10, 12, or 16 bytes, but later versions of the SCSI standard also allow for variable-length CDBs. The sense data 412 can include information about the error, such as the error code, the number of retry steps, and the LBA where the error was encountered, among others.

The address descriptor 414 is a physical memory address that indicates the actual physical location of the media error corresponding to the check condition error. If the check condition error did not result from a media error, then the address descriptor 414 may be set to zero. For any media error, such as a bad sector, the address descriptor 414 may be set to a non-zero value that indicates the physical memory address of the media location that returned the error.

It will be appreciated that the check condition data parameter 210 may include various other data values in addition to those described above. For example, the check condition data parameter 210 may include some padding in various data fields to accommodate data fields of varying length. The check condition data parameter 210 may also include descriptors that indicate the length of fields including padding, the length of the valid portion of the field, and the like.

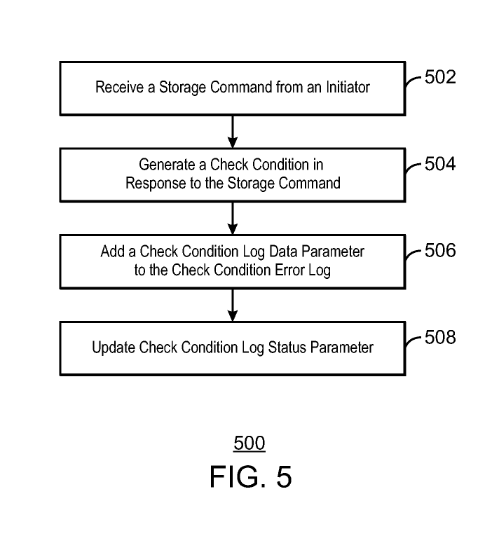

FIG. 5 is a process flow diagram of a method of operating a storage drive, in accordance with an embodiment. The method is referred to by the reference number 500 and may be implemented, for example, by the drive controller 200 of FIG. 2. The method may begin at block 502, wherein a storage command such as storage read or write is received from an initiator. The initiator may be the host 102 or the storage controller 112 shown in FIG. 1.

At block 504, an error is generated in response to the storage command. For example, the error may be a check condition error, which may be reported to the initiator. Other types of errors may include a BUSY status, RESERVATION CONFLICT status, and internal errors that are not reported to the initiator, among others.

At block 506, a check condition data parameter may be added to the check condition log page 114 shown in FIGS. 1 and 2. In embodiments, only check condition errors will cause a check condition data parameter to be added to the check condition log page. In embodiments, the check condition data parameter includes a physical memory address corresponding to a physical location of a storage element corresponding to the error. The physical memory address may be used, for example, to identify the physical storage element corresponding to the error, which may be defective.

In an embodiment, adding the check condition data parameter to the check condition log stored to the storage media may include adding the check condition data parameter based on check condition data temporarily held in a cache or buffer. Accordingly, data corresponding to the error may be gathered at the time of the error and stored to the cache. The check condition log may be periodically updated from the check condition data stored to the cache. Furthermore, as discussed above, upon reaching the last check condition data parameter that the check condition log can hold, new check condition data parameters may be wrapped around to the beginning of the check condition log.

At block 508, the drive controller may update the check condition log status parameter. For example, the drive controller may increment the number of errors 304 and the last parameter written 306 by one.

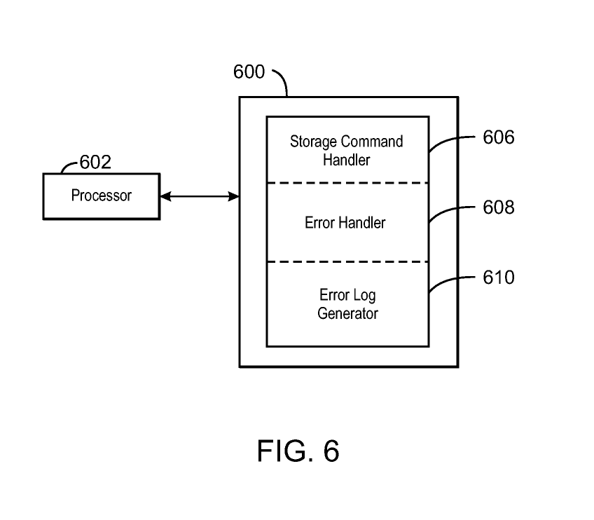

FIG. 6 is a block diagram showing a non-transitory, computer-readable medium that stores code for operating a drive controller, in accordance with an embodiment. The non-transitory, computer-readable medium is generally referred to by the reference number 600. The non-transitory, computer-readable medium 600 may correspond to any typical storage device that stores computer-implemented instructions, such as programming code or the like. For example, the non-transitory, computer-readable medium 600 may include one or more of a non-volatile memory, a volatile memory, and/or one or more storage media. Examples of non-volatile memory include, but are not limited to, electrically erasable programmable read only memory (EEPROM) and read only memory (ROM). Examples of volatile memory include, but are not limited to, static random access memory (SRAM), and dynamic random access memory (DRAM). Examples of storage media include, but are not limited to, magnetic disks, optical disks, flash memory, and the like. The non-transitory, computer-readable medium 600 may also be an Application Specific Integrated Circuit (ASIC) configured to execute the computer-implemented instructions.

A processor 602, which may be the drive controller 200 if FIG. 2, generally retrieves and executes the instructions stored in the non-transitory, computer-readable medium 600. A first region 606 may include a storage command handler configured to receive and process storage commands received from an initiator. A second region 608 may include an error handler configured to generate an error in the event that the requested storage operation cannot be processed, due for example, to a busy status, a reservation conflict, defective sector, and the like. The error handler may report the error to the initiator. If the error is a check condition error, the error handler may cause a new check condition data parameter to be added to a check condition log stored to the storage media. A third region 610 may include an error log generator configured to add the check condition data parameter to the error log stored to a storage media of the storage drive. The check condition data parameter may include the physical memory address corresponding to the physical location of the storage element corresponding to the error. In an embodiment, the error log generator also updates the check condition log status parameter 208, as discussed above.

Although shown as contiguous blocks, the software components can be stored in any order or configuration. For example, if the non-transitory, computer-readable medium 600 is a hard drive, the software components can be stored in non-contiguous, or even overlapping, sectors.

What is claimed is:

1. A method of operating a storage drive, comprising:
receiving a storage command from an initiator;
generating an error in response to the storage command; and
adding a check condition data parameter to a check condition log stored to a storage media of the storage drive;
wherein the check condition data parameter comprises a physical memory address corresponding to a physical location of a storage element corresponding to the error.

2. The method of claim 1, comprising:
gathering data corresponding to the error and storing the data to a cache; and
periodically updating the check condition log based on the check condition data stored to the cache.

3. The method of claim 1, wherein the check condition data parameter comprises information about whether the error is attributable to the physical location of the storage element corresponding to the error or whether the error is an artifact of a previous error at a different physical location.

4. The method of claim 1, wherein only check condition errors reported to the initiator are stored to the check condition log.

5. The method of claim 1, comprising overwriting the oldest check condition data parameter with a new check condition data parameter if a number of errors encountered exceeds a maximum number of errors that are storable to the storage media.

6. The method of claim 1, comprising updating a check condition log status parameter each time a new check condition data parameter is added to the check condition log.

7. A storage drive comprising:
a processor;
a storage medium;
a non-transitory, computer-readable medium comprising instructions configured to direct the processor to:
receive a storage command from an initiator;
generate an error in response to the storage command; and
add a check condition data parameter to a check condition log stored to a storage media of the storage drive, wherein the check condition data parameter comprises a physical memory address corresponding to a physical location of a storage element corresponding to the error.

8. The storage drive of claim 7, wherein the error comprises a check condition error reported to the initiator.

9. The storage drive of claim 7, wherein the storage drive comprises a solid state drive.

10. The storage drive of claim 7, wherein the storage drive comprises a hard disk drive.

11. The storage drive of claim 7, comprising a cache, wherein the non-transitory, computer-readable medium comprises instructions configured to:
direct the processor to gather check condition data corresponding to the error;
store the check condition data to the cache; and
periodically update the check condition log based on the check condition data stored to the cache.

12. The storage drive of claim 7, wherein the check condition log comprises a check condition log status parameter which is updated each time a new check condition data parameter is added to the check condition log.

13. The storage drive of claim 12, wherein the check condition log status parameter comprises:
a first value that indicates a maximum number of errors that can be stored to the check condition log;
a second value that indicates the number of errors encountered; and
a third value that indicates which of the check condition data parameters was a last check condition data parameter written to the check condition log.

14. The storage drive of claim 7, wherein the non-transitory, computer-readable medium comprises instructions configured to direct the processor to wrap newly encountered errors to a beginning of the check condition log if a number of errors encountered exceeds a maximum number of check condition data parameters that can be stored to the check condition log.

15. A non-transitory, computer-readable medium comprising code configured to direct a processor to:
receive a storage command from an initiator;
generate an error in response to the storage command; and
add a check condition data parameter to an check condition log stored to a storage media,
wherein the check condition data parameter comprises a physical memory address corresponding to a physical location of a storage element corresponding to the error.

16. The non-transitory, computer-readable medium of claim 15 comprising code configured to direct the processor to add the check condition data parameter to the check condition log only if the error is a check condition error reported to the initiator.

17. The non-transitory, computer-readable medium of claim 15 comprising code configured to direct the processor to update a check condition log status parameter of the check condition log each time a new check condition data parameter is added to the check condition log.

18. The non-transitory, computer-readable medium of claim 17 wherein the check condition log status parameter comprises:
a first value that indicates a maximum number of errors that can be stored to the check condition log;
a second value that indicates the number of errors encountered; and
a third value that indicates which of the check condition data parameters was a last check condition data parameter added to the check condition log.

19. The non-transitory, computer-readable medium of claim 15, comprising code configured to direct the processor to:
gather data corresponding to the error;
store the data to a cache; and
periodically update the error log based on the check condition data stored to the cache.

20. The non-transitory, computer-readable medium of claim 15, comprising code configured to direct the processor to overwrite the oldest check condition data parameter with a new check condition data parameter if a number of errors encountered exceeds a maximum number of errors that are storable to the storage media.
